(19) United States
(12) Patent Application Publication
(10) Pub. No.: US 2013/0128083 A1
(43) Pub. Date: May 23, 2013

(54) HIGH DYNAMIC RANGE IMAGE SENSING DEVICE AND IMAGE SENSING METHOD AND MANUFACTURING METHOD THEREOF

(71) Applicant: Chih-Min LIU, Tainan City (TW)

(72) Inventor: Chih-Min LIU, Tainan City (TW)

(73) Assignee: Himax Imaging Limited, Tainan City (TW)

(21) Appl. No.: 13/303,905

(22) Filed: Nov. 23, 2011

(51) Int. Cl. H04N 5/225; H05K 13/00

(52) U.S. Cl. 348/262; 29/592.1; 348/E05.024

(57) ABSTRACT

A high dynamic range (HDR) image sensing method is provided. The image sensor includes steps of: sensing an image with a long integration time by a first long integration time sensor; and sensing the image with a short integration time by a first short integration time sensor.

### BACKGROUND OF THE INVENTION

1. Field of the Invention

The present invention relates to an image sensing device, and in particular relates to a high dynamic range image sensing device which has long and short integration time sensors.

2. Description of the Related Art

For a conventional image sensor, a particular image capturing speed (i.e., exposure time or camera shutter speed) has to be determined and adjusted manually or automatically according to the illumination of the environment in order to quickly capture an image, for high resolution. However, there is a tradeoff between the image capturing speed and the resolution; that is, a rapid image capturing speed usually leads to low and poor resolution, while a slow image capturing speed is usually needed for high and good resolution. For video application, the image capturing speed also determines the frame rate.

In addition, in a high dynamic range environment, for example, capturing road condition images in a moving vehicle, the ordinary image sensor usually has poor color discrimination capabilities, especially in a dark environment.

Therefore, a high dynamic range image sensing device or a high dynamic range image sensing method, which captures images with high frame rate, high resolution, high color discrimination capabilities is desirable.

### BRIEF SUMMARY OF THE INVENTION

The present invention provides a high dynamic range (HDR) image sensing device, which at least comprises a first pair of image sensors, having a first long integration time sensor for sensing an image with a long integration time, and a first short integration time sensor, coupled to the first long integration time sensor, for sensing the image with a short integration time.

The present invention provides a high dynamic range (HDR) image sensing method, which comprises sensing an image with a long integration time by a first long integration time sensor, and sensing the image with a short integration time by a first short integration time sensor.

The present invention provides a high dynamic range (HDR) image sensing device manufacturing method, which comprises forming a plurality of first pairs of image sensors on a first row of a wafer, wherein each of the first pairs of image sensors has a first long integration time sensor and a first short integration time sensor coupled to each other.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 shows a high dynamic range (HDR) image sensing device according to an embodiment of the present invention;

FIG. 2 shows the high dynamic range image sensing device 200 of the present invention for 3D image capturing;

FIG. 3 shows the high dynamic range image sensing device 300 of the present invention for multi-dimension image capturing;

FIGS. 4A and 4B respectively show the second and the third pair of image sensors;

FIG. 5 shows a Bayer color filter, which is commonly used in the prior art;

FIGS. 6A-6C show the color filters 600 of the present invention according to three embodiments of the present invention;

FIG. 7A is a flow chart of the high dynamic range image sensing method according to an embodiment of the present invention;

FIG. 7B is a flow chart of the high dynamic range image sensing method according to another embodiment of the present invention;

FIGS. 8A-8C respectively show a section of a wafer and a plurality of high dynamic range image sensing devices disposed thereon according to the embodiments of the present invention;

FIG. 9A is a flow chart of the method for manufacturing a high dynamic range image sensing devices in one embodiments of the invention;

FIG. 9B is a flow chart of the method for manufacturing a high dynamic range image sensing device according to another embodiment of the invention;

FIG. 9C is a flow chart of the method for manufacturing a high dynamic range image sensing device according to embodiments of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

### High Dynamic Range Image Sensing Device

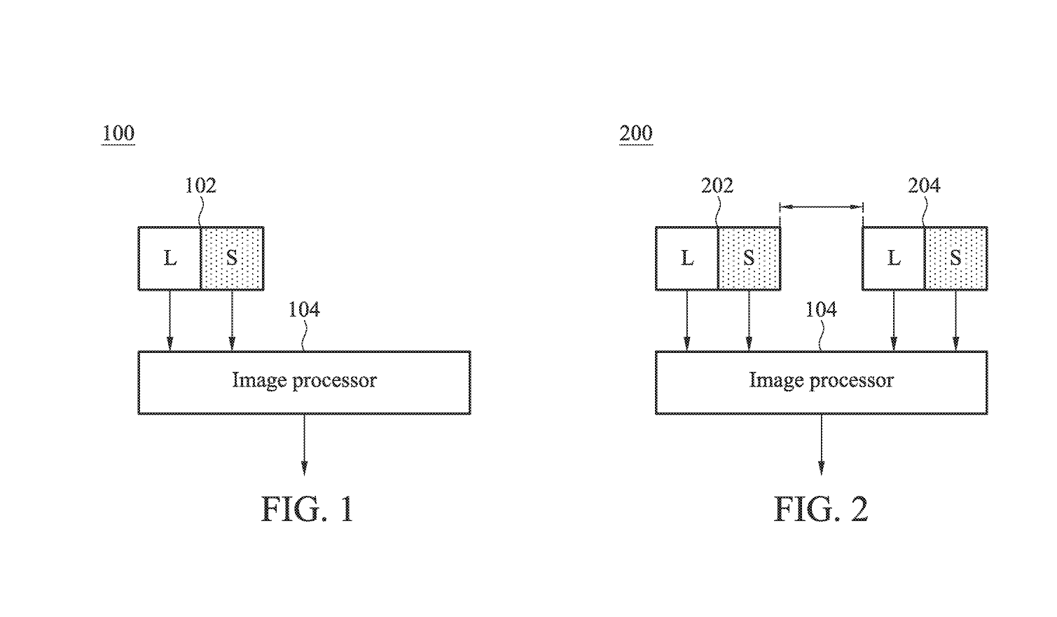

FIG. 1 shows a high dynamic range (HDR) image sensing device according to a first embodiment of the present invention. The high dynamic range image sensing device 100 is used to sense an image in a high dynamic range. For example, the high dynamic range image sensing device 100 is for example a car surveillance recorder, a video event data recorder or a video parking image sensor, that records video or images.

The high dynamic range image sensing device 100 at least comprises a first pair of image sensors 102. The first pair of image sensors 102 has a first long integration time sensor L and a first short integration time sensor S. The first long integration time sensor L and the first short integration time sensor S are coupled and closely adjacent to each other. The first long integration time sensor is used for sensing the image with a long integration time, thus having better image sensitivity of the dark area, and the first short integration time sensor S is used for sensing the image with a short integration time, thus outputting image data with better sensitivity of the bright area, or with a higher frame rate. In a better embodiment, the first long and short integration time sensor L and S should be manufactured as small as possible because the smaller the size of the image sensors L and S, the smaller the view angle difference between the captured images respectively obtained by them.

In the embodiment as shown in FIG. 1, only one pair of image sensors 102 is used. The high dynamic range image sensing device 100 having only one pair of image sensors is used for capturing ordinary 2D images.

In one embodiment, the images sensed by the first long and short integration time sensor L and S will be sent to an image processor 104 for further processing to obtain images with high resolution, high frame rate and high dynamic range. For one simplified example, a high dynamic range image may be obtained by combination of the brighter part of the image from the sensor S and the darker part of the image from the sensor L.

FIG. 2 shows a high dynamic range image sensing device 200 of a second embodiment of the present invention for 3D image capturing. In this embodiment, the high dynamic range image sensing device 200 has two first pairs of image sensors, and each pair has a long integration time sensor L and a short integration time sensor S. As shown in FIG. 2, one of the first pairs of image sensors 202 is on the left side (for example, disposed on a left stereo camera), while the other of the first pair of image sensors 204 is on the right side (for example, disposed on a left stereo camera). The left and the right pair of image sensors 202 and 204 are separated by a distance, which mimic human eyes in order to create stereo vision.

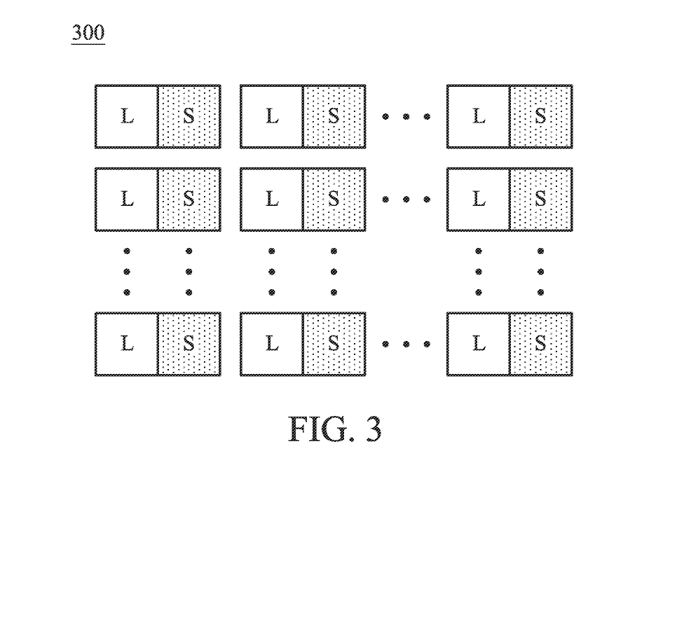

FIG. 3 shows a high dynamic range image sensing device 300 of a third embodiment of the present invention for multi-dimension image capturing. In this embodiment, the high dynamic range image sensing device 300 has three or more pairs of image sensors, and each pair has a long integration time sensor L and a short integration time sensor S. In this embodiment, each of the image sensors receives images with different angles, thus creating the vision of compound eyes. The image sensor array shown in FIG. 3 is only for illustration purposes and should not be used to limit the present invention. Those skilled in the art can implement various image arrays for creating various types of compound eye visions, for example, apposition eye, superposition eye, or parabolic superposition eye visions, which conform with the advantages of the present embodiment of the invention, such as improving on high sensitivity (high resolution) and high frame rate, by using the long and short integration time sensors at the same time.

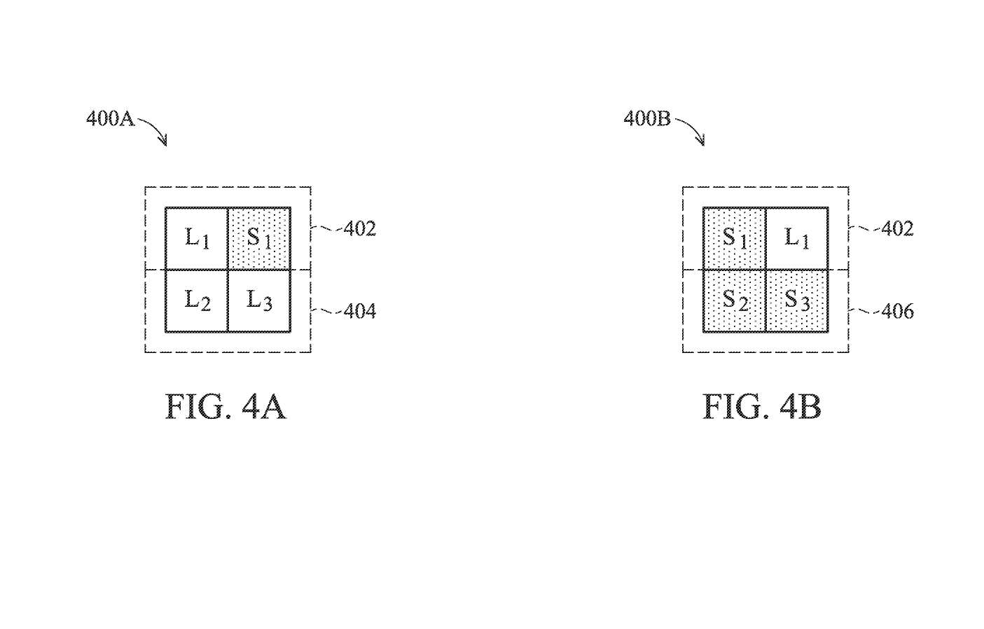

FIGS. 4A and 4B respectively show the image sensing devices according to the fourth and the fifth embodiments of the present invention. In the fourth embodiment, the high dynamic range image sensing device 400A in FIG. 4A includes a first pair of image sensors 402 and a second pair of image sensors 404. The first pair of image sensors 402 has a first long integration time sensor L1 and a first short integration time sensor S2, and the second pair of image sensors 404 has a second long integration time sensor L2 and a third long integration time sensor L3. Both of the second and the third long integration time sensors L2 and L3 are used for sensing the image with a long integration time. The long integration time sensors L1, L2 and L3 may be respectively exposed at different exposure times, such that the images, respectively from the long integration time sensors L1, L2 and L3 and the short integration image sensor S1, record more details.

In the fifth embodiment, the high dynamic range image sensing device 400B in FIG. 4B includes a first pair of image sensors 402 and a third pair of image sensors 406. The first pair of image sensors 402 has a first long integration time sensor L1 and a first short integration time sensor S1, and the third pair of image sensors 406 has a second short integration time sensor S2 and a third short integration time sensor S3. Both of the second and the third short integration time sensors S2 and S3 are used for sensing the image with a long integration time. Note that, for illustration, the first pair of image sensors 402 is above the second or third pair of image sensors 404 or 406, and the first long and short integration time sensors L1 and S1 are arranged from left to right; however, the present invention should not be limited thereto.

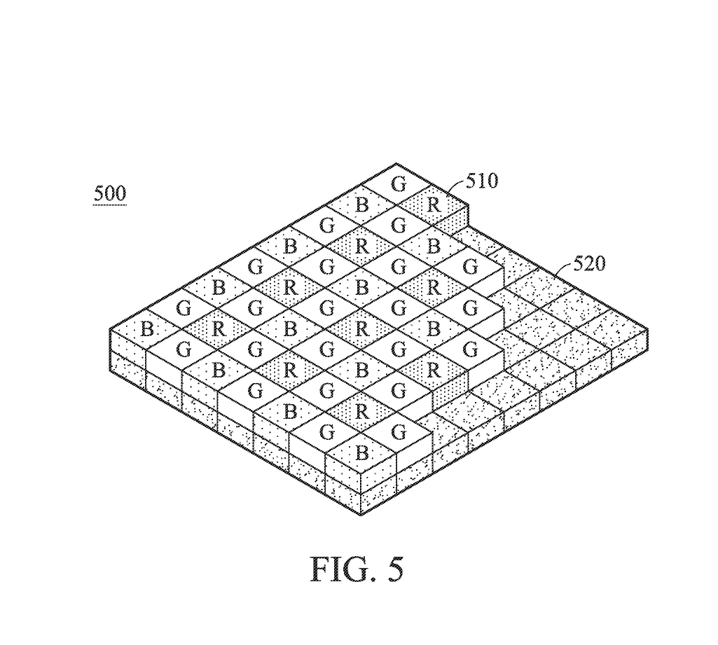

FIG. 5 shows a structure of an image sensor 500, which includes a color filter array 510 and a pixel array 520. The color filter array 510, of Bayer pattern in this example, includes red, blue and green color filters on the pixel array 520 and uses twice as many green color filters as red color filters or blue color filters (50% green, 25% red and 25% blue) to mimic the physiology of the human eyes. The image sensors L and S in the above illustrated embodiments may use the structure as the image sensor 500.

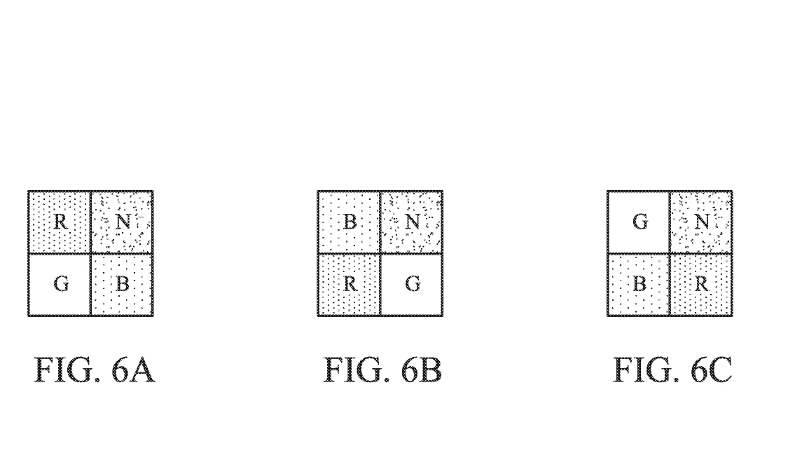

FIGS. 6A-6C respectively show the image sensing devices according to a sixth, seventh and eighth embodiment of the present invention. In the sixth embodiment, the image sensing device 600 includes sensors 601, 602, 603 and 604. The sensor 601 includes a pixel array (not shown) and a red color filter, labeled as R, that covers the entire pixel array of the sensor 601. The sensor 602 includes a pixel array (not shown) and a transparent color filter, labeled as N, that covers the entire pixel array of the sensor 602. The sensor 603 includes a pixel array (not shown) and a green color filter, labeled as G, that covers the entire pixel array of the sensor 603. The sensor 604 includes a pixel array (not shown) and a blue color filter, labeled as B, that covers the entire pixel array of the sensor 604. In a better embodiment, the sensors 601-604 should be manufactured as small as possible because the smaller the size, the smaller the view angle difference between the captured images respectively obtained by them. For sensor 602, it should be noted that the transparent color filter N is not necessarily exist and, in one example, the sensor 602 may include the pixel array without any color filter.

In one example, the sensors 601, 603 and 604 may correspond to a long integration time, and the sensor 602 may correspond to a short integration time. In this example, the sensor 602 may be exposed in a short integration time to acquire an image with great details in the brighter part of a scene, and the sensors 601, 603 and 604 with RGB color filters may be exposed in a long integration time to acquire images with good color discrimination capability in the darker part of the scene. In another example, the sensors 601, 603 and 604 may correspond to a short integration time, and the sensor 602 may correspond to a long integration time.

In the seventh embodiment in FIG. 6B, the image sensing device 610 includes sensors 611, 612, 613 and 614. The sensor 611 includes a pixel array (not shown) and a red color filter, labeled as R, that covers the entire pixel array of the sensor 611. The sensor 612 includes a pixel array (not shown) and a transparent color filter, labeled as N, that covers the entire pixel array of the sensor 612. The sensor 613 includes a pixel array (not shown) and a green color filter, labeled as G, that covers the entire pixel array of the sensor 613. The sensor 614 includes a pixel array (not shown) and a blue color filter, labeled as B, that covers the entire pixel array of the sensor 614. In one example, the sensors 611, 613 and 614 may correspond to a long integration time, and the sensor 612 may correspond to a short integration time. In another example, the sensors 611, 613 and 614 may correspond to a short integration time, and the sensor 612 may correspond to a long integration time.

In the eighth embodiment in FIG. 6C, the image sensing device 620 includes sensors 621, 622, 623 and 624. The sensor 621 includes a pixel array (not shown) and a red color filter, labeled as R, that covers the entire pixel array of the sensor 621. The sensor 622 includes a pixel array (not shown) and a transparent color filter, labeled as N, that covers the entire pixel array of the sensor 622. The sensor 623 includes a pixel array (not shown) and a green color filter, labeled as G, that covers the entire pixel array of the sensor 623. The sensor 624 includes a pixel array (not shown) and a blue color filter, labeled as B, that covers the entire pixel array of the sensor 624. In one example, the sensors 621, 623 and 624 may correspond to a long integration time, and the sensor 622 may correspond to a short integration time. In another example, the sensors 621, 623 and 624 may correspond to a short integration time, and the sensor 622 may correspond to a long integration time.

### High Dynamic Range Image Sensing Method

In addition to the high dynamic range image sensing device, the present invention further provides a high dynamic range image sensing method.

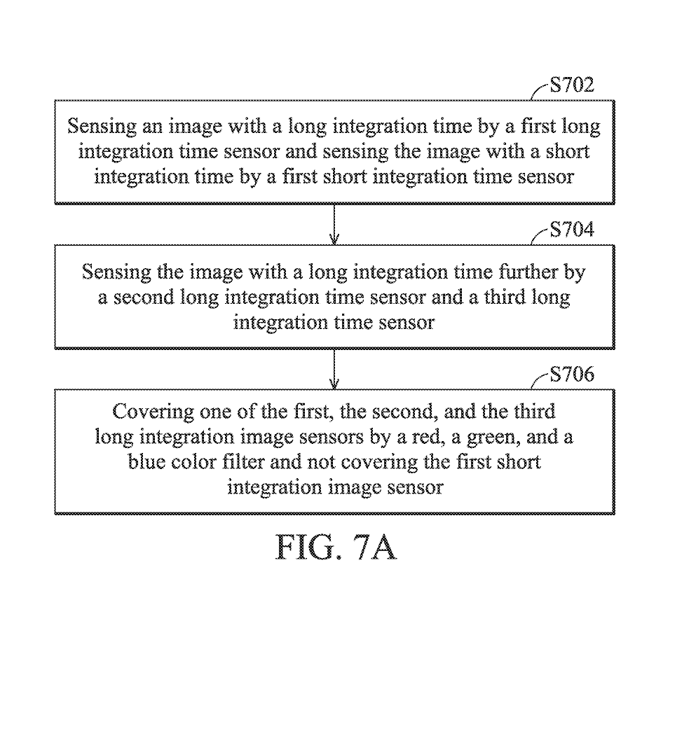

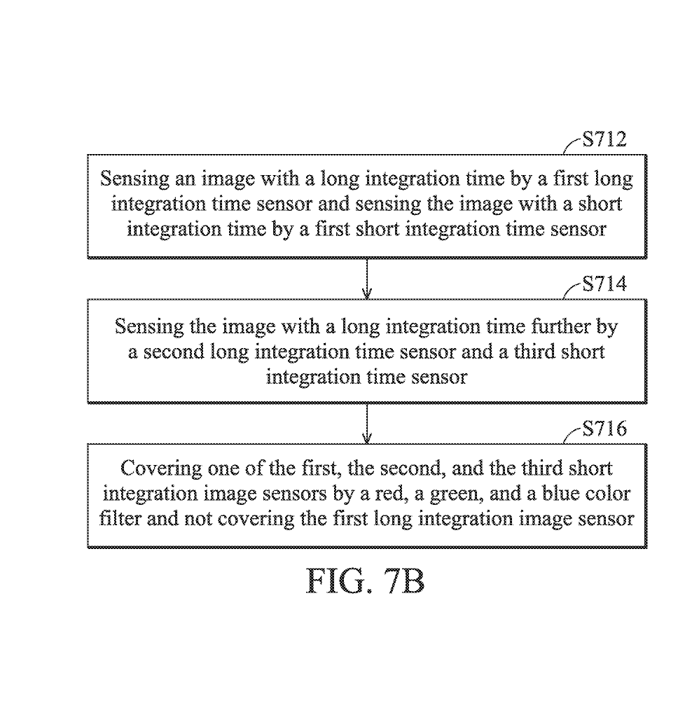

FIG. 7A is a flow chart of the high dynamic range image sensing method according to an embodiment of the present invention. The method 700A, in this embodiment, comprises: in step S702, sensing an image with a long integration time by a first long integration time sensor (e.g., L1 as shown in FIG. 4A) and sensing the image with a short integration time by a first short integration time sensor (e.g., S1 as shown in FIG. 4A); in step S704, sensing the image with a long integration time further by a second long integration time sensor and a third long integration time sensor (e.g., L2 and L3 as shown in FIG. 4A); and in step S706, covering one of the first, the second, and the third long integration image sensors (i.e., L1, L2 and L3) by a red, a green, and a blue color filter (e.g., RGB color filters as shown in FIGS. 6A-6C) and not covering the first short integration image sensor (i.e., S1) (including covering the first short integration image sensor with a transparent color filter).

FIG. 7B is a flow chart of the high dynamic range image sensing method according to another embodiment of the present invention. The method 700B, in this embodiment, comprises: in step S712, sensing an image with a long integration time by a first long integration time sensor (e.g., L1 as shown in FIG. 4B) and sensing the image with a short integration time by a first short integration time sensor (e.g., S1 as shown in FIG. 4B); in step S714, sensing the image with a long integration time further by a second long integration time sensor and a third short integration time sensor (e.g., S2 and S3 as shown in FIG. 4B); and in step S716, covering one of the first, the second, and the third short integration image sensors (i.e., S1, S2 and S3) by a red, a green, and a blue color filter (e.g., RGB color filters as shown in FIGS. 6A-6C) and not covering the first long integration image sensor (i.e., L1) (including covering the first long integration image sensor with a transparent color filter).

Since it is believed that those skilled in the art can well appreciate the methods 700A and 700B of the present invention by reading such descriptions together with FIGS. 1-6, the methods 700A and 700B of the present invention will not be further discussed in detail.

Note that, in the present invention, each of the RGB color filters covers an entire image sensor (for example, having a 1024×768 pixels) rather than an individual pixel of the image sensors, thus the size thereof is larger and can be manufactured more easily than the Bayer color filters of the prior art. Moreover, the color filters of the present invention with bigger sizes can substantially reduce the crosstalk or blooming effect in a high dynamic range image sensor.

### Method for Manufacturing a High Dynamic Range Image Sensing Device

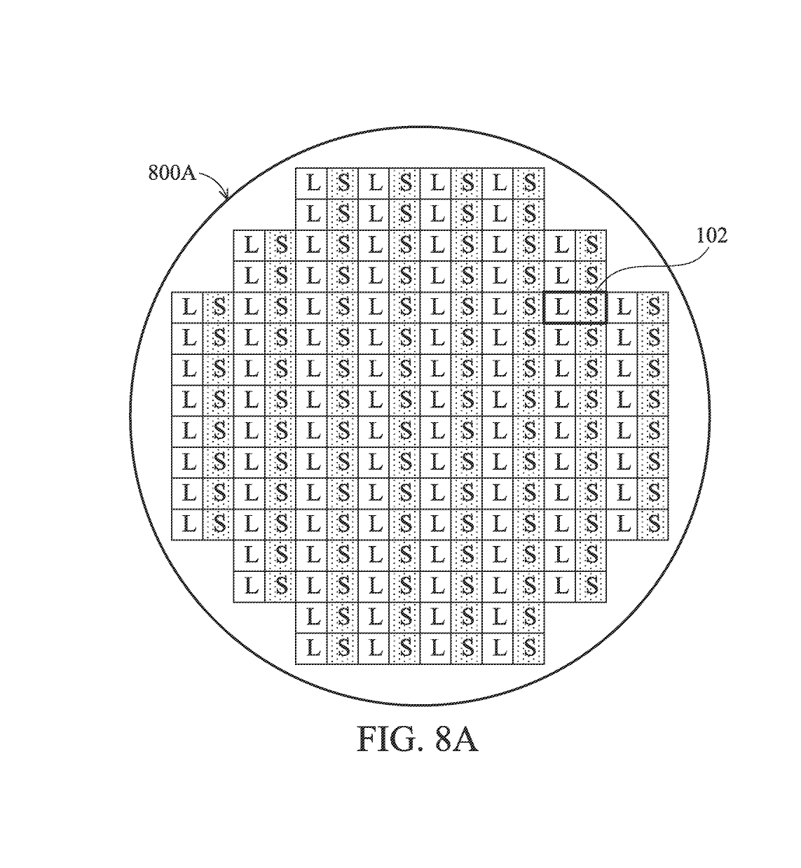

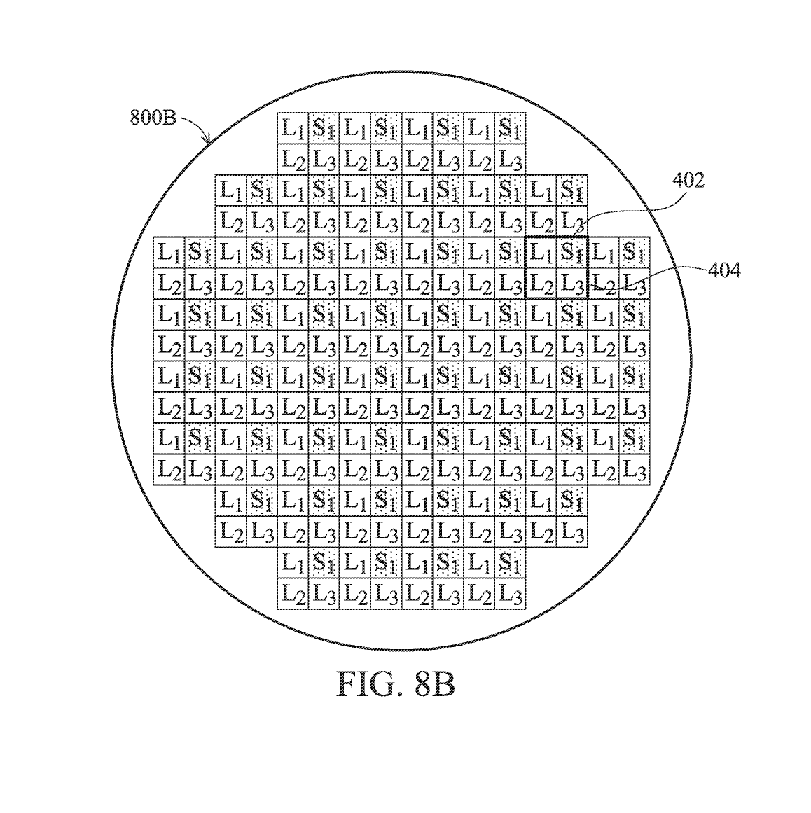

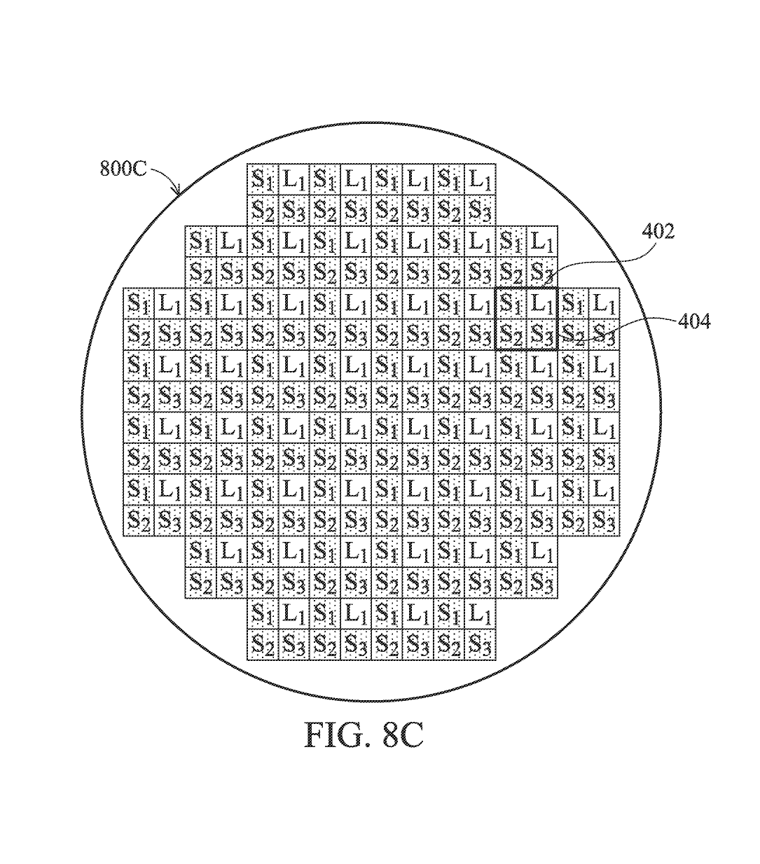

In addition to the high dynamic range image sensing device and method, the present invention further provides method for manufacturing a high dynamic range image sensing device, where, in particular, the method manufactures a plurality of high dynamic range image sensing devices, such as camera chips, in a batch on a wafer level module (WLM). FIGS. 8A-8C respectively show a section of a wafer and a plurality of high dynamic range image sensing devices disposed thereon according to the embodiments of the present invention.

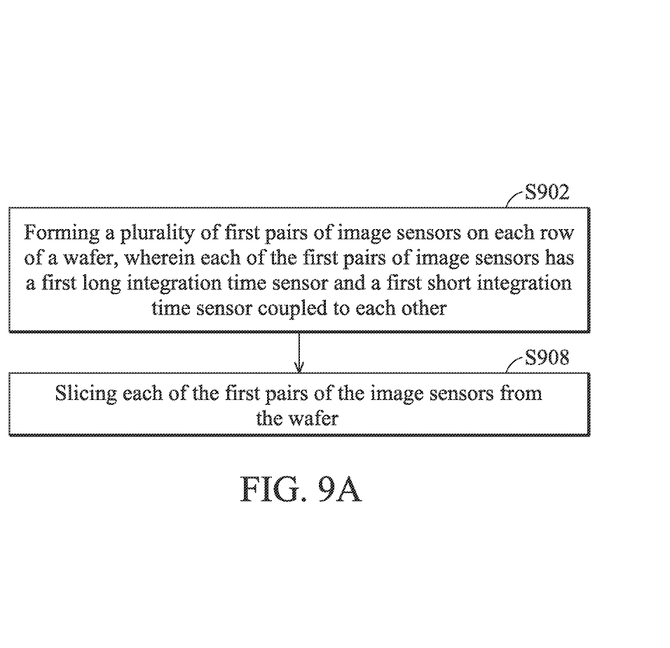

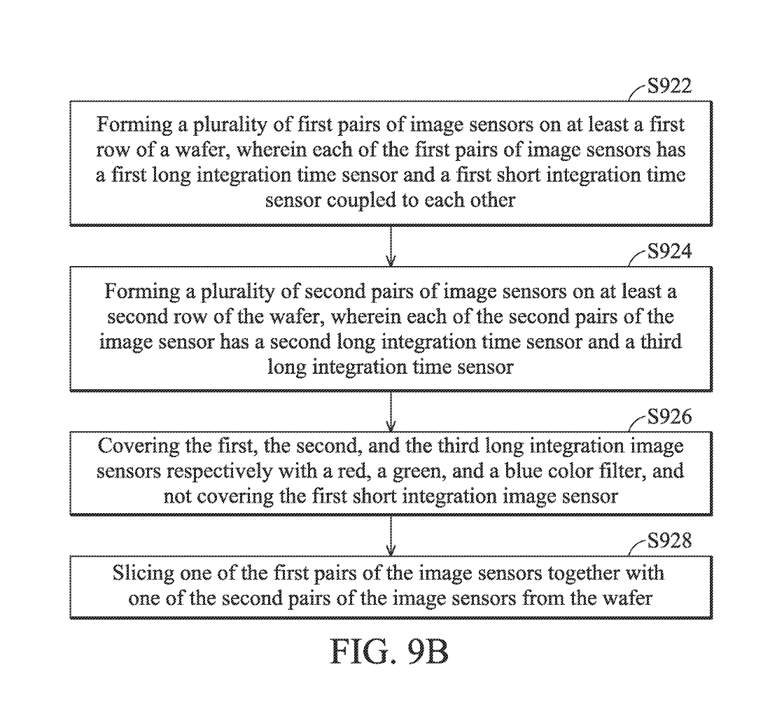

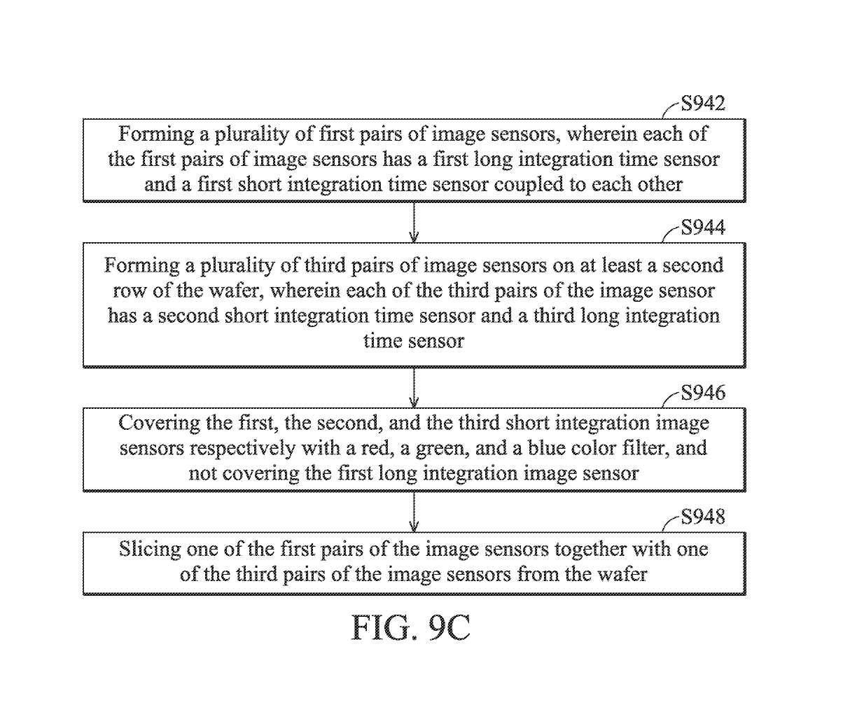

FIG. 9A is a flow chart of the method for manufacturing a high dynamic range image sensing device in one embodiments of the invention. Please refer to FIGS. 8A and 9A, wherein the method 900A, in this embodiment, comprises: in step S902, forming a plurality of first pairs of image sensors (e.g., 102 as shown in FIGS. 1 and 8A) on each row of a wafer (800A), wherein each of the first pairs of image sensors (e.g., 102) has a first long integration time sensor (i.e., L in FIGS. 1 and 8A) and a first short integration time sensor (i.e., S in FIG. 1 FIGS. 1 and 8A) coupled to each other as shown in FIG. 8A. The method in this embodiment may further comprise a step S908 of slicing each of the first pairs of the image sensors from the wafer.

FIG. 9B is a flow chart of the method for manufacturing a high dynamic range image sensing device according to another embodiment of the invention. Please refer to FIGS. 8B and 9B, wherein the method 900B, in this embodiment, comprises: in step S922, forming a plurality of first pairs of image sensors (e.g., 402 as shown in FIGS. 2 and 8B) on at least a first row of a wafer (800B), wherein each of the first pairs of image sensors (e.g., 402 in FIGS. 2 and 8B) has a first long integration time sensor (i.e., L1 in FIGS. 2 and 8B) and a first short integration time sensor (i.e., S1 in FIGS. 2 and 8B) coupled to each other; in step S924, forming a plurality of second pairs of image sensors (e.g. 404 as shown in FIGS. 2 and 8B) on at least a second row of the wafer (800B), wherein each of the second pairs (e.g., 404 as shown in FIGS. 2 and 8B) of the image sensor has a second long integration time sensor (e.g., L2 as shown in FIGS. 2 and 8B) and a third long integration time sensor (e.g., L3 as shown in FIGS. 2 and 8B). The method in this embodiment further comprises: in step S926, covering the first, the second, and the third long integration image sensors (e.g., L1, L2, L3 as shown in FIGS. 2 and 8B) respectively with a red, a green, and a blue color filter (e.g., RGB in FIG. 6A-6C), and not covering the first short integration image sensor (e.g., S1 as shown in FIGS. 2 and 8B) (including covering the first short integration image sensor with a transparent color filter). Although only the first and the second row of the wafer are described for illustration in this embodiment, the present invention should not be limited thereto, and those skilled in the art can form the third, the fourth, and the other rows of the wafer according to the spirit of the method described above. In addition, the method in this embodiment may further comprise a step S928 of slicing one of the first pairs of the image sensors (e.g., 402 as shown in FIGS. 2 and 8B) together with one of the second pairs of the image sensors (e.g., 404 as shown in FIGS. 2 and 8B) from the wafer (800B).

FIG. 9C is a flow chart of the method for manufacturing a high dynamic range image sensing device according to another embodiment of the invention. Please refer to FIGS. 8C and 9C, wherein the method 900C, in this embodiment, comprises: in step S942, forming a plurality of first pairs of image sensors (e.g., 402 as shown in FIGS. 2 and 8C) on at least a first row of a wafer (800C), wherein each of the first pairs of image sensors (e.g., 402 in FIGS. 2 and 8C) has a first long integration time sensor (i.e., L1 in FIGS. 2 and 8C) and a first short integration time sensor (i.e., S1 in FIGS. 2 and 8C) coupled to each other; in step S944, forming a plurality of third pairs of image sensors (e.g. 406 as shown in FIGS. 2 and 8C) on at least a second row of the wafer (800C), wherein each of the third pairs (e.g., 406 as shown in FIGS. 2 and 8C) of the image sensor has a second short integration time sensor (e.g., S2 as shown in FIGS. 2 and 8C) and a third long integration time sensor (e.g., S3 as shown in FIGS. 2 and 8C). The method in this embodiment further comprises: in step S946, covering the first, the second, and the third short integration image sensors (e.g., S1, S2, S3 as shown in FIGS. 2 and 8C) respectively with a red, a green, and a blue color filter (e.g., RGB in FIG. 6A-6C), and not covering the first long integration image sensor (e.g., L1 as shown in FIGS. 2 and 8C) (including covering the first long integration image sensor with a transparent color filter). Although only the first and the second row of the wafer are described for illustration in this embodiment, the present invention should not be limited thereto, and those skilled in the art can form the third, the fourth, and the other rows of the wafer according to the spirit of the method described above. In addition, the method in this embodiment may further comprise a step S948 of slicing one of the first pairs of the image sensors (e.g., 402 as shown in FIGS. 2 and 8C) together with one of the third pairs of the image sensors (e.g., 406 as shown in FIGS. 2 and 8C) from the wafer (800C).

The methods for manufacturing high dynamic range image sensing devices 900A-900C of the present invention have the advantages which have been described previously, so they will not be further repeated for brevity.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A high dynamic range (HDR) image sensing device, at least comprising:
a first pair of image sensors, having
a first long integration time sensor for sensing an image with a long integration time; and
a first short integration time sensor, coupled to the first long integration time sensor, for sensing the image with a short integration time.

2. The HDR image sensing device as claimed in claim 1, further comprising:
a second pair of image sensors, coupled to the first pair of image sensors in parallel, having:
a second long integration time sensor and a third long integration time sensor coupled to the second long integration time sensor, both for sensing the image with a long integration time.

3. The HDR image sensing device as claimed in claim 2, further comprising:
a red, a green, and a blue color filter, wherein each of the red, the green, and the blue filter covers one of the first, the second, and the third long integration image sensors, and does not cover the first short integration image sensor.

4. The HDR image sensing device as claimed in claim 1, further comprising:
a third pair of image sensors, coupled to the first pair of image sensors in parallel, having:
a second short integration time sensor and a third short integration time sensor coupled to the second short integration time sensor, both for sensing the image with a short integration time.

5. The HDR image sensing device as claimed in claim 4, further comprising:
a red, a green, and a blue color filter, wherein each of the red, the green, and the blue filter covers one of the first, the second, and the third short integration image sensors, and does not cover the first long integration image sensor.

6. The HDR image sensing device as claimed in claim 4, further comprising:
a red, a green, and a blue color filter, wherein each of the red, the green, and the blue filter covers one of the first, the second, and the third short integration image sensors, and the first long integration image sensor is covered with a transparent color filter.

7. The HDR image sensing device as claimed in claim 4, further comprising an image processor for producing a high dynamic range image based on images from the first long integration time sensor and the first short integration time sensor.

8. A high dynamic range (HDR) image sensing method, comprising:
sensing an image with a long integration time by a first long integration time sensor; and
sensing the image with a short integration time by a first short integration time sensor.

9. The HDR image sensing method as claimed in claim 8, further comprising:
sensing the image with a long integration time further by a second long integration time sensor and a third long integration time sensor.

10. The HDR image sensing method as claimed in claim 9, further comprising:
covering one of the first, the second, and the third long integration image sensors by a red, a green, and a blue color filter; and
not covering the first short integration image sensor.

11. The HDR image sensing method as claimed in claim 8, further comprising:
sensing the image with a short integration time further by a second short integration time sensor and a third short integration time sensor.

12. The HDR image sensing device as claimed in claim 11, further comprising:
covering one of the first, the second, and the third short integration image sensors by a red, a green, and a blue color filter; and
not covering the first long integration image sensor with any color filter.

13. The HDR image sensing device as claimed in claim 11, further comprising:
covering one of the first, the second, and the third short integration image sensors by a red, a green, and a blue color filter; and
covering the first long integration image sensor with a transparent filter.

14. The HDR image sensing device as claimed in claim 11, further comprising:
producing a high dynamic range image based on images from the first long integration time sensor and the first short integration time sensor.

15. A method for manufacturing a high dynamic range (HDR) image sensing device, comprising:
forming a plurality of first pairs of image sensors on at least a first row of a wafer, wherein each of the first pairs of image sensors has a first long integration time sensor and a first short integration time sensor coupled to each other.

16. The method for manufacturing HDR image sensing device as claimed in claim 15, further comprising:
forming the plurality of first pairs of image sensors on each row of a wafer.

17. The method for manufacturing HDR image sensing device as claimed in claim 15, further comprising:
forming a plurality of second pairs of image sensors on at least a second row of a wafer, wherein each of the second pairs of the image sensors has a second long integration time sensor and a third long integration time sensor.

18. The method for manufacturing HDR image sensing device as claimed in claim 17, further comprising:
covering the first, the second, and the third long integration image sensors respectively with a red, a green, and a blue color filter; and
not covering the first short integration image sensor.

19. The method for manufacturing HDR image sensing device as claimed in claim 15, further comprising:
forming a plurality of third pairs of image sensors on a second row of a wafer, wherein each of the third pairs of the image sensors has a second short integration time sensor and a third short integration time sensor.

20. The method for manufacturing HDR image sensing device as claimed in claim 19, further comprising:
covering one of the first, the second, and the third short integration image sensors by a red, a green, and a blue color filter; and
not covering the first long integration image sensor with any color filter.

21. The method for manufacturing HDR image sensing device as claimed in claim 19, further comprising:
covering one of the first, the second, and the third short integration image sensors by a red, a green, and a blue color filter; and
covering the first long integration image sensor with a transparent color filter.

22. The method for manufacturing HDR image sensing device as claimed in claim 19, further comprising:
producing a high dynamic range image based on images from the first long integration time sensor and the first short integration time sensor.
